(19) United States
(12) Patent Application Publication
(10) Pub. No.: US 2024/0353488 A1
(43) Pub. Date: Oct. 24, 2024

(54) TECHNOLOGIES FOR AUTOMATED TEST PATTERN GENERATION FOR LOGIC CIRCUITS WITH BOOLEAN SATISFIABILITY ANALYSIS

(71) Applicant: AUBURN UNIVERSITY, Auburn, AL (US)

(72) Inventors: Ujjwal Guin, Auburn, AL (US); Yadi Zhong, Auburn, AL (US)

(21) Appl. No.: 18/641,741

(22) Filed: Apr. 22, 2024

Related U.S. Application Data
(60) Provisional application No. 63/461,025, filed on Apr. 21, 2023.

(51) Int. Cl. G01R 31/3183

(52) U.S. Cl. CPC G01R 31/3183

(57) ABSTRACT

Technologies for automated test pattern generation include a computing device that identifies one or more stuck-at faults in a logic circuit. The computing device inserts a key gate in the logic circuit at a stuck-at fault to generate a locked logic circuit. The computing device performs a Boolean satisfiability attack to determine an input test pattern associated with the fault and, if no input test pattern exists, identify the fault as redundant. The computing device may identify multiple undetected faults in the logic circuit. The computing device may generate and analyze a separate locked circuit for each undetected fault and/or generate and analyze a locked circuit that models all of the undetected faults. The computing device may test a device under test with all of the generated input test patterns associated with the undetected faults. Other embodiments are described and claimed.

### CROSS-REFERENCE TO RELATED APPLICATION

This application claims priority to U.S. Provisional Application Ser. No. 63/461,025, filed Apr. 21, 2023, the entire disclosure of which is hereby incorporated by reference.

### STATEMENT REGARDING FEDERALLY SPONSORED RESEARCH

This invention was made with Government support under CNS-1755733 awarded by the National Science Foundation (NSF). The Government has certain rights in the invention.

### BACKGROUND

As the role of integrated circuits (ICs) in critical infrastructure increases, the importance of avoiding the escape of manufacturing defects also increases. Testing of ICs plays a vital role in detecting defects in manufactured ICs. Currently, automated test pattern generation (ATPG) tools exist and are capable of generating test patterns for stuck-at faults, delay faults, bridging faults, and a few other fault models. For example, an existing ATPG tool is TetraMAX II, produced by Synopsys Inc. of Mountain View, California. However, existing ATPG tools are not capable of detecting all stuck-at faults in a digital circuit, particularly for large circuits.

Logic locking has been proposed to counter semiconductor IP piracy. In a common logic locking scheme, a logic design is obfuscated by adding locks to the logic to generate a locked logic circuit. These locks are typically constructed from XOR gates inserted in the logic circuit, which each receive a secret key bit as input. Accordingly, the locked logic circuit produces correct output—that is, output that matches the original, unlocked logic circuit-only when provided with a secret key, which is typically a vector of binary values stored in a tamper-proof memory. Subramanyan et al. demonstrated a Boolean satisfiability-based attack (SAT-attack) that is capable of determining the correct secret key for a locked logic circuit given the locked logic circuit and an oracle that provides the correct (i.e., unlocked) output for a given input.

### SUMMARY

According to one aspect of the disclosure, a computing device for logic circuit test pattern generation includes a logic preprocessor, a lock circuit generator, and a fault analyzer. The logic preprocessor is configured to identify a first stuck-at fault for testing with a logic circuit, wherein the first stuck-at fault is associated with a first signal of the logic circuit and a digital logic stuck-at value. The lock circuit generator is configured to insert a key gate in the logic circuit at the first stuck-at fault for testing to generate a locked logic circuit. The key gate receives a key value and a value of the first signal associated with the first stuck-at fault. When the key value is a first key value the key gate generates the digital logic stuck-at value, and when the key value is a second key value the key gate propagates the value of the first signal. The fault analyzer is configured to determine whether an input test pattern associated with the first stuck-at fault exists by performance of a Boolean satisfiability attack on the locked logic circuit. The fault analyzer is further configured to identify the first stuck-at fault as a redundant fault in response to a determination that an input test pattern associated with the first stuck-at fault does not exist.

In an embodiment, the computing device further includes a test manager to input the input test pattern associated with the first stuck-at fault to a device under test that comprises the logic circuit and to compare an output pattern received from the logic circuit of the device under test in response to inputting of the input test pattern to an expected output.

In an embodiment, the first stuck-at fault comprises a stuck-at-1 fault or a stuck-at-0 fault. In an embodiment, to insert the key gate in the logic circuit at the first stuck-at fault comprises to insert an AND gate for a stuck-at-1 fault and to insert an OR gate for a stuck-at-0 fault. In an embodiment, to insert the key gate in the logic circuit further comprises to insert a buffer at a logic fanout segment in the logic circuit.

In an embodiment, the logic preprocessor is further to obtain a representation of the logic circuit, wherein the representation comprises a netlist. In an embodiment, the logic preprocessor is further to convert sequential logic of the representation of the logic circuit to combinational logic; wherein to identify the first stuck-at fault comprises to identify the first stuck-at fault in the combinational logic.

In an embodiment, the computing device further comprises an automatic test pattern generation tool to perform an automatic test pattern generation process with the logic circuit; and identify a plurality of undetected stuck-at faults in the logic circuit in response to performance of the automatic test pattern generation process. The plurality of undetected stuck-at faults comprises the first stuck-at fault.

In an embodiment, the logic preprocessor is to identify a plurality of stuck-at faults, the plurality of stuck-at faults comprising the first stuck-at fault. The lock circuit generator is to, for each stuck-at fault of the plurality of stuck-at faults, insert a key gate in the logic circuit at the corresponding stuck-at fault to generate a plurality of locked logic circuits. The fault analyzer is to, for each stuck-at fault of the plurality of stuck-at faults, determine whether an input test pattern associated with the corresponding stuck-at fault exists by performance of the Boolean satisfiability attack on each locked logic circuit of the plurality of locked logic circuits and and to identify the corresponding stuck-at fault as a redundant fault in response to a determination that an input test pattern associated with the corresponding stuck-at fault does not exist. In an embodiment, to determine whether an input test pattern associated with the corresponding stuck-at fault exists comprises to perform an iteration of the Boolean satisfiability attack on the corresponding locked logic circuit; determine whether the corresponding locked logic circuit is satisfiable in response to performance of the iteration of the Boolean satisfiability attack; and determine that the corresponding stuck-at fault is a redundant fault in response to a determination that the corresponding locked logic circuit is not satisfiable. In an embodiment, to determine the input test pattern associated with the corresponding stuck-at fault comprises to determine a distinguishing input pattern for the corresponding locked logic circuit in response to a determination that the corresponding locked logic circuit is satisfiable, wherein the input test pattern comprises the distinguishing input pattern. In an embodiment, the fault analyzer is further to verify a key value matches an expected key value associated with the stuck-at fault, wherein the expected key value is based on the stuck-at value of the stuck-at fault; and to perform the iteration of the Boolean satisfiability attack comprises to determine the key value for the locked logic circuit. In an embodiment, to perform the iteration of the Boolean satisfiability attack comprises to construct a miter circuit based on the corresponding locked logic circuit, the miter circuit comprising a first copy of the corresponding locked logic circuit, a second copy of the corresponding locked logic circuit, and an exclusive OR gate that receives output from the first copy and the second copy; assign a first key value to the first copy and a second key value to the second copy; and determine whether an input pattern exists such that the miter circuit can equal logical one.

In an embodiment, the logic preprocessor is to identify a plurality of stuck-at faults, the plurality of stuck-at faults comprising the first stuck-at fault. The lock circuit generator is to insert a plurality of key gates in the logic circuit to generate the locked logic circuit, wherein each key gate corresponds to a stuck-at fault of the plurality of stuck-at faults. The fault analyzer is to determine an input test pattern associated with each stuck-at fault of the plurality of stuck-at faults that is not a redundant fault by the performance of the Boolean satisfiability attack on the locked logic circuit. In an embodiment, to perform the Boolean satisfiability attack comprises to determine a plurality of distinguishing input patterns for the locked logic circuit, wherein the plurality of distinguishing input patterns comprises the input test pattern associated with each stuck-at fault that is not a redundant fault. In an embodiment, the fault analyzer is further to verify that each key value of a key vector matches an expected key value associated with a stuck-at fault, wherein the expected key value is based on the stuck-at value of the stuck-at fault; and to perform the Boolean satisfiability attack further comprises to determine the key vector for the locked logic circuit.

According to another aspect, a method for logic circuit test pattern generation, the method comprising identifying, by a computing device, a first stuck-at fault for testing with a logic circuit, wherein the first stuck-at fault is associated with a first signal of the logic circuit and a digital logic stuck-at value; inserting, by the computing device, a key gate in the logic circuit at the first stuck-at fault for testing to generate a locked logic circuit, wherein the key gate receives a key value and a value of the first signal associated with the first stuck-at fault, and wherein when the key value is a first key value the key gate generates the digital logic stuck-at value, and wherein when the key value is a second key value the key gate propagates the value of the first signal; determining, by the computing device, whether an input test pattern associated with the first stuck-at fault exists by performing a Boolean satisfiability attack on the locked logic circuit; and identifying, by the computing device, the first stuck-at fault as a redundant fault in response to determining that an input test pattern associated with the first stuck-at fault does not exist.

In an embodiment, the method further comprises inputting, by the computing device, the input test pattern associated with the first stuck-at fault to a device under test that comprises the logic circuit; and comparing, by the computing device, an output pattern received from the logic circuit of the device under test in response to inputting the input test pattern to an expected output.

In an embodiment, the first stuck-at fault comprises a stuck-at-1 fault or a stuck-at-0 fault. In an embodiment, inserting the key gate in the logic circuit at the first stuck-at fault comprises inserting an AND gate for a stuck-at-1 fault and inserting an OR gate for a stuck-at-0 fault. In an embodiment, inserting the key gate in the logic circuit further comprises inserting a buffer at a logic fanout segment in the logic circuit.

In an embodiment, the method further comprises obtaining, by the computing device, a representation of the logic circuit, wherein the representation comprises a netlist. In an embodiment, the method further comprises converting, by the computing device, sequential logic of the representation of the logic circuit to combinational logic; wherein identifying the first stuck-at fault comprises identifying the first stuck-at fault in the combinational logic.

In an embodiment, the method further comprises performing, by the computing device, an automatic test pattern generation process with the logic circuit; and identifying, by the computing device, a plurality of undetected stuck-at faults in the logic circuit in response to performing the automatic test pattern generation process; wherein the plurality of undetected stuck-at faults comprises the first stuck-at fault.

In an embodiment, the method further comprises identifying, by the computing device, a plurality of stuck-at faults, the plurality of stuck-at faults comprising the first stuck-at fault; inserting, by the computing device, for each stuck-at fault of the plurality of stuck-at faults, a key gate in the logic circuit at the corresponding stuck-at fault to generate a plurality of locked logic circuits; and determining, by the computing device, for each stuck-at fault of the plurality of stuck-at faults, whether an input test pattern associated with the corresponding stuck-at fault exists by performing the Boolean satisfiability attack on each locked logic circuit of the plurality of locked logic circuits; and identifying, by the computing device, for each stuck-at fault of the plurality of stuck-at faults, the corresponding stuck-at fault as a redundant fault in response to determining that an input test pattern associated with the corresponding stuck-at fault does not exist. In an embodiment, determining whether an input test pattern associated with the corresponding stuck-at fault exists comprises performing an iteration of the Boolean satisfiability attack on the corresponding locked logic circuit; determining whether the corresponding locked logic circuit is satisfiable in response to performing the iteration of the Boolean satisfiability attack; and determining that the corresponding stuck-at fault is a redundant fault in response to determining that the corresponding locked logic circuit is not satisfiable. In an embodiment, determining the input test pattern associated with the corresponding stuck-at fault comprises determining a distinguishing input pattern for the corresponding locked logic circuit in response to determining that the corresponding locked logic circuit is satisfiable, wherein the input test pattern comprises the distinguishing input pattern. In an embodiment, the method further comprises verifying, by the computing device, a key value matches an expected key value associated with the stuck-at fault, wherein the expected key value is based on the stuck-at value of the stuck-at fault; wherein performing the iteration of the Boolean satisfiability attack comprises determining the key value for the locked logic circuit. In an embodiment, performing the iteration of the Boolean satisfiability attack comprises constructing a miter circuit based on the corresponding locked logic circuit, the miter circuit comprising a first copy of the corresponding locked logic circuit, a second copy of the corresponding locked logic circuit, and an exclusive OR gate that receives output from the first copy and the second copy; assigning a first key value to the first copy and a second key value to the second copy; and determining whether an input pattern exists such that the miter circuit can equal logical one.

In an embodiment, the method further comprises identifying, by the computing device, a plurality of stuck-at faults, the plurality of stuck-at faults comprising the first stuck-at fault; inserting, by the computing device, a plurality of key gates in the logic circuit to generate the locked logic circuit, wherein each key gate corresponds to a stuck-at fault of the plurality of stuck-at faults; and determining, by the computing device, an input test pattern associated with each stuck-at fault of the plurality of stuck-at faults that is not a redundant fault by performing the Boolean satisfiability attack on the locked logic circuit. In an embodiment, performing the Boolean satisfiability attack comprises determining a plurality of distinguishing input patterns for the locked logic circuit, wherein the plurality of distinguishing input patterns comprises the input test pattern associated with each stuck-at fault that is not a redundant fault. In an embodiment, the method further comprises verifying, by the computing device, that each key value of a key vector matches an expected key value associated with a stuck-at fault, wherein the expected key value is based on the stuck-at value of the stuck-at fault; wherein performing the Boolean satisfiability attack further comprises determining the key vector for the locked logic circuit.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified block diagram of at least one embodiment of a system for automated test pattern generation for logic circuits using Boolean satisfiability analysis;

FIG. 2 is a simplified block diagram of an environment that may be established by a computing device of FIG. 1;

FIG. 3 is a simplified flow diagram of at least one embodiment of a method for automated test pattern generation that may be executed by the computing device of FIGS. 1 and 2;

FIG. 4 is a simplified flow diagram of at least one embodiment of a method for a single-fault approach for determining test patterns and identifying redundant faults that may be executed in connection with FIG. 3;

FIG. 5 is a schematic diagram illustrating key gate fault modeling circuits that may be generated by the computing device of FIGS. 1-2;

FIG. 6 is a schematic diagram illustrating a miter circuit that may be generated by the computing device of FIGS. 1-2;

FIG. 7 is a simplified flow diagram of at least one embodiment of a method for a multiple-fault approach for determining test patterns and identifying redundant faults that may be executed in connection with FIG. 3;

FIG. 8 is a schematic diagram illustrating key gate fault modeling circuits that may be generated by the computing device of FIGS. 1-2;

FIG. 9 is a pseudocode diagram illustrating at least one potential embodiment of the methods of FIGS. 3-4 and 7; and

FIG. 10 is a pseudocode diagram illustrating at least one potential embodiment of a Boolean satisfiability attack function that may be executed in connection with the pseudocode of FIG. 9.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

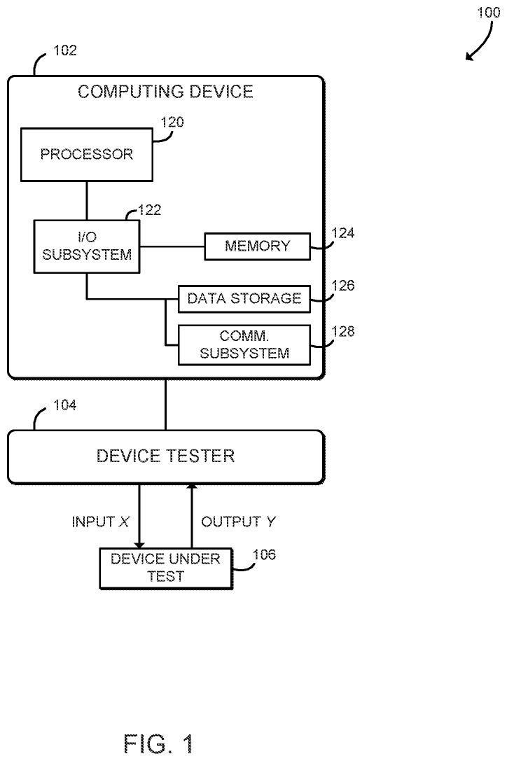

Referring now to FIG. 1, an illustrative system 100 for automated test pattern generation for logic circuits using Boolean satisfiability analysis includes quasi-centralized, secure biometric data management includes a computing device 102 and in some embodiments a device tester 104 that may be coupled to a device under test 106. The device under test 106 may be embodied as one or more integrated circuits or other digital logic devices. In use, as described further below, the computing device 102 uses a Boolean satisfiability analysis to automatically determine one or more test patterns for use with the device under test 106. The test patterns may each be embodied as a vector or other collection of binary values, and the device tester 106 may apply those test patterns as inputs X to the device under test 106. The device tester 106 receives output Y from the device under test 106, which may be compared to a predetermined expected output in order to detect faults in the device under test 106. As described further below, the system 100 may generate a collection of test patterns that are capable of detecting every possible non-redundant “stuck-at” fault in the device under test, including stuck-at faults that are undetectable by typical automated test pattern generation (ATPG) tools. A stuck-at fault is an error condition in which a signal or other line of the device under test is incorrectly held at a fixed logical value, and includes stuck-at-0 faults and stuck-at-1 faults. A redundant stuck-at fault is not observable in the output of the device under test 106. As described below, the system 100 is also capable of identifying redundant stuck-at faults of the device under test 106 that do not need test coverage. Accordingly, the system 100 is capable of generating test patterns with 100% coverage of the non-redundant stuck-at faults of the device under test 106, which is not possible with existing ATPG tools. Further, the system 100 may be used to generate an optimized set of test patterns or an otherwise reduced in size collection of test patterns, which may reduce the amount of time required to test the device under test 106.

For example, Table 1, below, lists experimental results that were achieved by an illustrative embodiment of the system 100. In an experiment, 25 combinational benchmark circuits from ITC'99 were analyzed with a commercially available ATPG tool. Simple benchmark circuits where the commercially available ATPG tool detected all stuck-at faults were excluded. Table 1 lists the benchmark name, the total number of stuck-at faults in the benchmark (TF), the number of undetected faults (UF) and the fault coverage for the commercial ATPG tool. As shown, for each of the benchmarks shown in Table 1, the commercial ATPG did not detect all of the total stuck-at faults. For example, those undetected faults may include faults that were only possibly detected, undetectable, ATPG untestable, or not detected. Table 1 also lists, for each benchmark, the number of redundant faults (RF) and detected faults (DF) generated by the system 100 based on the faults that were undetected by the commercial ATPG tool. Accordingly, when processed by the system 100, all of those undetected faults were categorized as either a redundant fault (for which no test pattern coverage is needed) or a detected fault with an associated test input pattern. Thus, as shown, the system 100 in combination with the commercial ATPG tool was capable of reaching 100% test coverage for stuck-at faults for all of the benchmarks tested.

TABLE 1
Stuck-at fault analysis summary for ITC'99 benchmarks.

| | | Existing ATPG Tool | | System 100 | | |
|---|---|---|---|---|---|---|
| | Total | Undetected | Fault | Redundant | Detected | Total |
| | Faults | Faults | Coverage | Faults | Faults | Coverage |
| Benchmark | (TF) | (UF) | (%) | (RF) | (DF) | (%) |
| b04_opt_C | 3554 | 5 | 99.86 | 5 | 0 | 100 |
| b04_C | 4144 | 50 | 98.79 | 50 | 0 | 100 |
| b05_opt_C | 3272 | 7 | 99.85 | 3 | 4 | 100 |
| b05_C | 5850 | 1103 | 81.15 | 1103 | 0 | 100 |
| b07_opt_C | 2456 | 1 | 99.96 | 1 | 0 | 100 |
| b07_C | 2470 | 6 | 99.76 | 6 | 0 | 100 |
| b11_opt_C | 3318 | 2 | 99.94 | 2 | 0 | 100 |
| b11_C | 4378 | 166 | 96.21 | 161 | 5 | 100 |
| b12_opt_C | 6048 | 1 | 99.98 | 1 | 0 | 100 |
| b13_C | 1928 | 80 | 95.85 | 80 | 0 | 100 |
| b14_opt_C | 58265 | 319 | 99.46 | 319 | 0 | 100 |
| b14_C | 35844 | 38 | 99.89 | 38 | 0 | 100 |
| b15_opt_C | 48220 | 1298 | 97.33 | 1287 | 11 | 100 |
| b15_C | 53470 | 1518 | 97.16 | 1518 | 0 | 100 |
| b17_opt_C | 157418 | 3170 | 97.99 | 3144 | 26 | 100 |
| b17_C | 192174 | 4277 | 97.77 | 4276 | 1 | 100 |
| b20_opt_C | 79748 | 104 | 99.87 | 104 | 0 | 100 |
| b20_C | 118298 | 684 | 99.44 | 631 | 53 | 100 |
| b21_opt_C | 80504 | 106 | 99.87 | 106 | 0 | 100 |
| b21_C | 120436 | 694 | 99.43 | 686 | 8 | 100 |
| b22_opt_C | 114556 | 169 | 99.85 | 169 | 0 | 100 |
| b22_C | 175510 | 857 | 99.52 | 796 | 61 | 100 |
| b18_opt_C | 469602 | 558 | 99.88 | 544 | 14 | 100 |
| b18_C | 672242 | 3764 | 99.44 | 3760 | 4 | 100 |
| b19_C | 1355584 | 8559 | 99.37 | 8460 | 99 | 100 |

Referring again to FIG. 1, the computing device 102 may be embodied as any type of device capable of performing the functions described herein. For example, the computing device 102 may be embodied as, without limitation, a workstation, a server computer, a desktop computer, a laptop computer, a network appliance, a web appliance, a smartphone, a tablet computer, a consumer electronic device, a distributed computing system, a multiprocessor system, and/or any other computing device capable of performing the functions described herein. As shown in FIG. 1, the illustrative computing device 102 includes a processor 120, an I/O subsystem 122, memory 124, a data storage device 126, and communication circuitry 128. Of course, the computing device 102 may include other or additional components, such as those commonly found in a computer workstation (e.g., various input/output devices), in other embodiments. Additionally, in some embodiments, one or more of the illustrative components may be incorporated in, or otherwise form a portion of, another component. For example, the memory 124, or portions thereof, may be incorporated in the processor 120 in some embodiments. Additionally, in some embodiments, the computing device 102 may be embodied as a “virtual server” formed from multiple computing devices distributed across a network and operating in a public or private cloud. Accordingly, although the computing device 102 is illustrated in FIG. 1 as embodied as a single computing device, it should be appreciated that the computing device 102 may be embodied as multiple devices cooperating together to facilitate the functionality described below.

The processor 120 may be embodied as any type of processor or compute engine capable of performing the functions described herein. For example, the processor may be embodied as a single or multi-core processor(s), digital signal processor, microcontroller, or other processor or processing/controlling circuit. Similarly, the memory 124 may be embodied as any type of volatile or non-volatile memory or data storage capable of performing the functions described herein. In operation, the memory 124 may store various data and software used during operation of the computing device 102 such as operating systems, applications, programs, libraries, and drivers. The memory 124 is communicatively coupled to the processor 120 via the I/O subsystem 122, which may be embodied as circuitry and/or components to facilitate input/output operations with the processor 120, the memory 124, and other components of the computing device 102. For example, the I/O subsystem 122 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. In some embodiments, the I/O subsystem 122 may form a portion of a system-on-a-chip (SoC) and be incorporated, along with the processor 120, the memory 124, and other components of the computing device 102, on a single integrated circuit chip.

The data storage device 126 may be embodied as any type of device or devices configured for short-term or long-term storage of data such as, for example, memory devices and circuits, memory cards, hard disk drives, solid-state drives, or other data storage devices. The communication circuitry 128 of the computing device 102 may be embodied as any communication circuit, device, or collection thereof, capable of enabling communications between the computing device 102, the third-party device 106, the computing device 102, and/or other remote devices. The communication circuitry 128 may be configured to use any one or more communication technology (e.g., wireless or wired communications) and associated protocols (e.g., Ethernet, Bluetooth®, Wi-Fi®, WiMAX, etc.) to effect such communication.

The device tester 104 may be embodied as any semiconductor test equipment, automated test equipment, IC tester, logic tester, wafer tester, or other device capable of performing the operations described herein. In some embodiments, one or more functions of the device tester 104 may be incorporated in or otherwise performed by another device, such as the computing device 102.

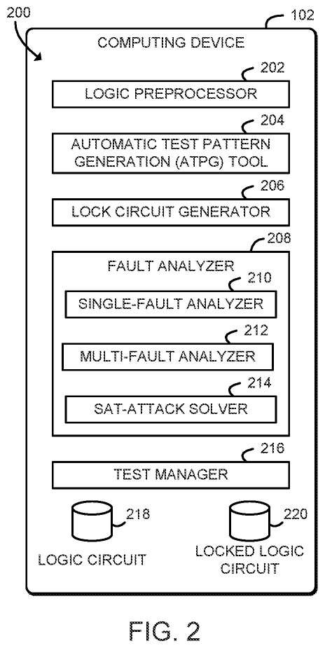

Referring now to FIG. 2, in the illustrative embodiment, the computing device 102 establishes an environment 200 during operation. The illustrative environment 200 includes a logic preprocessor 202, an automatic test pattern generation (ATPG) tool 204, a lock circuit generator 206, a fault analyzer 208, and a test manager 216. The various components of the environment 200 may be embodied as hardware, firmware, software, or a combination thereof. As such, in some embodiments, one or more of the components of the environment 200 may be embodied as circuitry or a collection of electrical devices (e.g., logic preprocessor circuitry 202, ATPG circuitry 204, lock circuit generator circuitry 206, fault analyzer circuitry 208, and/or test manager circuitry 212). It should be appreciated that, in such embodiments, one or more of those components may form a portion of the processor, the I/O subsystem, and/or other components of the computing device 102.

The logic preprocessor 202 may be configured to obtain a representation of a logic circuit 218, such as a netlist. The logic preprocessor 202 may be further configured to convert sequential logic of the representation of the logic circuit 218 to combinational logic. The logic preprocessor 202 is further configured to identify one or more stuck-at faults for testing with the logic circuit 218. Each stuck-at fault is associated with a corresponding signal of the logic circuit 218 and a digital logic stuck-at value. For example, each stuck-at fault may be a stuck-at-1 fault or a stuck-at-0 fault.

The ATPG tool 204 may be configured to perform an automatic test pattern generation process with the logic circuit 218, and to identify any undetected stuck-at faults in the logic circuit 218. Undetected stuck-at faults may include stuck-at faults identified by the logic preprocessor 202 but not detected by the ATPG tool 204. Further processing by the computing device 102 may be limited to those undetected stuck-at faults.

The lock circuit generator 206 is configured to insert a key gate in the logic circuit 218 at a stuck-at fault for testing to generate a locked logic circuit 220. The inserted key gate receives a key value and a value of the signal associated with that stuck-at fault. When the key value is one of the possible key values (e.g., logic one or zero) the key gate generates the digital logic stuck-at value (e.g., stuck-at-0 or stuck-at-1), and wherein when the key value is the other possible key value the key gate propagates the value of the corresponding signal. In some embodiments, inserting the key gate may include inserting an AND gate for a stuck-at-1 fault and inserting an OR gate for a stuck-at-0 fault. In some embodiments, inserting the key gate in the logic circuit 218 further includes inserting a buffer at a logic fanout segment in the logic circuit 218. In some embodiments, the lock circuit generator 206 is configured to separately insert a key gate in the logic circuit 218 at the corresponding stuck-at fault for each remaining stuck-at fault to generate multiple locked logic circuits 216. Additionally or alternatively, in some embodiments the lock circuit generator 206 is configured to insert multiple key gates in the logic circuit 218 to generate the locked logic circuit 220, where each key gate corresponds to a stuck-at fault of the remaining stuck-at faults.

The fault analyzer 208 is configured to determine whether an input test pattern associated with a stuck-at fault exists by performing a Boolean satisfiability attack on the locked logic circuit 220. The fault analyzer 208 is further configured to identify a stuck-at fault as a redundant fault in response to determining that an input test pattern associated with that stuck-at fault does not exist. In some embodiments, the Boolean satisfiability attack may be performed by a sub-component, such as the SAT-attack solver 214. In a single-fault approach in which separate locked logic circuits 220 are generated for each stuck-at fault, the fault analyzer 208 is configured to determine whether an input test pattern associated with each stuck-at fault exists by performing a Boolean satisfiability attack on each locked logic circuit 220 of the multiple of locked logic circuits 220. In this approach, the fault analyzer 208 is further configured to identify each stuck-at fault as a redundant fault if an input test pattern associated with that stuck-at fault does not exist Determining whether an input test pattern associated with a stuck-at fault exists may include performing an iteration of the Boolean satisfiability attack on the corresponding locked logic circuit 220, determining whether the corresponding locked logic circuit is satisfiable, and determining that the corresponding stuck-at fault is a redundant fault if the corresponding locked logic circuit is not satisfiable. Determining the input test pattern associated with the corresponding stuck-at fault may include determining a distinguishing input pattern for the corresponding locked logic circuit 220 if the corresponding locked logic circuit 220 is satisfiable. The input test pattern is this distinguishing input pattern. Performing the iteration of the Boolean satisfiability attack may include constructing a miter circuit based on the corresponding locked logic circuit 220, and determining whether an input pattern exists such that the miter circuit can equal logical one.

In a multi-fault approach in which a single locked logic circuit 220 is generated for multiple stuck-at faults, the fault analyzer 208 is further configured to determine an input test pattern associated with each stuck-at fault of the multiple stuck-at faults that is not a redundant fault by performing the Boolean satisfiability attack on the locked logic circuit 220. Performing the Boolean satisfiability attack may include determining multiple distinguishing input patterns for the locked logic circuit 220. The determined distinguishing input patterns include the input test patterns associated with each stuck-at fault that is not a redundant fault. Performing the Boolean satisfiability attack may further include determining a key vector for the locked logic circuit 220, and the fault analyzer 208 may be further configured to verify that each key value of the key vector matches an expected key value associated with a stuck-at fault. Each expected key value is based on the stuck-at value of the corresponding stuck-at fault. In some embodiments, those features may be performed by one or more sub-components, such as a single-fault analyzer 210 or a multi-fault analyzer 212.

The test manager 216 is configured to input one or more input test patterns associated stuck-at faults to a device under test 106 that includes the logic circuit 218. The test manager 216 is further configured to compare an output pattern received from the logic circuit 218 of the device under test 106 to an expected output.

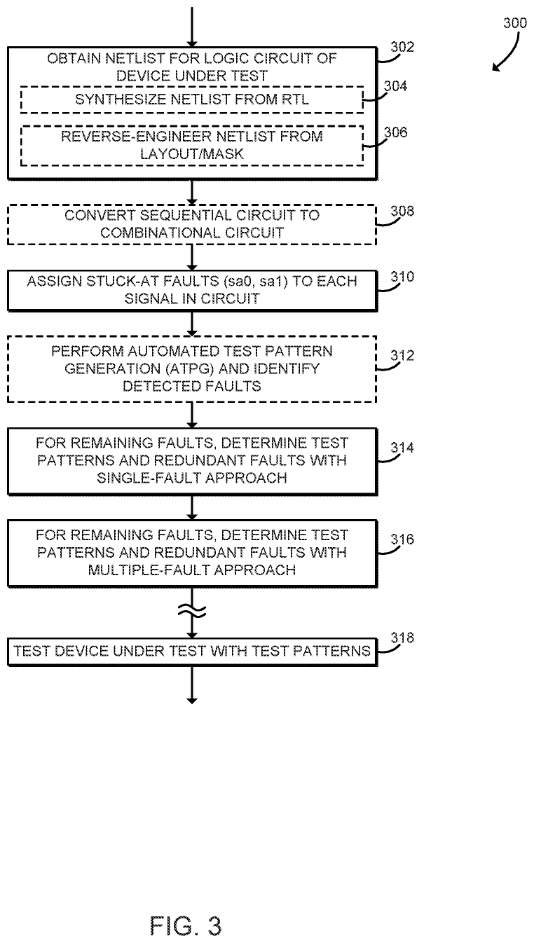

Referring now to FIG. 3, in use, the computing device 102 may execute a method 300 for automated test pattern generation. It should be appreciated that, in some embodiments, the operations of the method 300 may be performed by one or more components of the environment 200 of the computing device 102 as shown in FIG. 2. The method 300 begins with block 302, in which the computing device 102 obtains a netlist or other gate-level representation for a logic circuit 218 of the device under test 106. The computing device 102 may translate, convert, compile, or otherwise obtain the representation of the logic circuit 218 in any appropriate format that represents logical functions and signals of the device under test 106. In some embodiments, in block 304 the computing device 102 may synthesize a netlist from a register transfer level (RTL) representation of the logic circuit 218. In some embodiments, in block 306 the computing device 102 may reverse-engineer a netlist from a layout/mask of the device under test 106.

In some embodiments, in block 308, the computing device 102 may convert sequential logic or another sequential circuit of the logic circuit 218 into a combinational logic. The computing device 102 may use any appropriate technique for converting sequential logic. For example, scan-chain insertion may be performed to convert the sequential design to a combinational one so that ATPG can generate test patterns efficiently.

In block 310, the computing device 102 assigns stuck-at faults to each signal in the logic circuit 218. A stuck-at fault is a failure mode in which a logical signal is “stuck” at a particular logical value (e.g., logical zero or one) and does not correctly change values in response to inputs. Accordingly, stuck-at faults include stuck-at-zero faults (also called “sa0” faults) in which the logical signal is always zero regardless of input, and stuck-at-one faults (also called “sa1” faults) in which the logical signal is always one regardless of input. The computing device 102 may assign both an sa0 and an sa1 fault to each signal in the logic circuit 218, for example by recording an sa0 and sa1 fault for each node, line, or other signal in the logic circuit 218. When assigning both an sa0 and sa1 fault to the same signal, the faults may be inserted serially. As described further below, in some embodiments, the computing device 102 may assign separate sa0, sa1 faults to each segment in a digital fanout or fan-in, even if those lines are included in the same node for analysis purposes.

In some embodiments, in block 312 the computing device 102 performs automatic test pattern generation (ATPG) on the logic circuit 218 using the ATPG tool 204. For example, the computing device 102 may process the logic circuit 218 using one or more commercially available ATPG tools 204, such as TetraMax II by Synopsis Inc. or other commercially available ATPG tool. After ATPG analysis, the computing device 102 determines which of the sa0, sa1 faults assigned to the logic circuit 218 were detected by the ATPG tool 204. Those detected faults are covered by the one or more input test patterns generated by the ATPG tool 204 and thus may be removed from further analysis by the computing device 102. For example, the computing device 102 may generate a list of undetected sa0, sa1 faults including those faults that were not detected by the ATPG tool 204 and thus are not covered by the input test patterns generated by the ATPG tool 204.

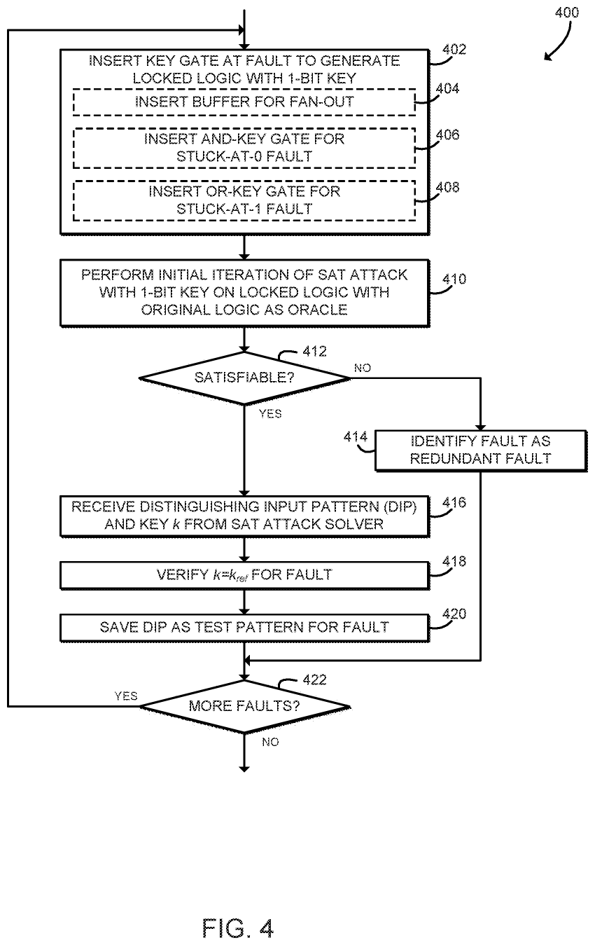

In block 314, for the remaining sa, sa1 faults (e.g., assigned sa0, sa1 faults in the logic circuit 218 less any faults detected by the ATPG tool 204), the computing device 102 determines input test patterns and identifies redundant faults with a single-fault approach. As described further below, each of the remaining sa0, sa1 faults is either a redundant fault (in which no input test pattern is possible or required) or a non-redundant fault for which an input test pattern is determined. In the single-fault approach, separate equivalent locked logic circuits 220 are generated based on the logic circuit 218 for each remaining fault, and a Boolean satisfiability (SAT) attack is performed to determine whether that fault is redundant and, if not, the associated input test pattern. One potential embodiment of a method for a single-fault approach is described further below in connection with FIG. 4.

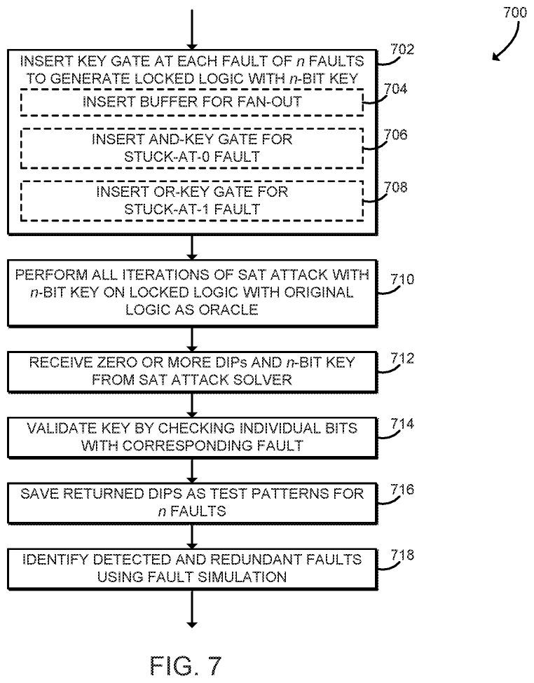

In block 314, for the same remaining sa0, sa1 faults (e.g., assigned sa0, sa1 faults in the logic circuit 218 less any faults detected by the ATPG tool 204), the computing device 102 determines input test patterns and identifies redundant faults with a multiple-fault approach. The multiple fault approach of block 316 may be performed in addition to or as an alternative to the single-fault approach of block 314. As described further below, each of the remaining sa0, sa1 faults is either a redundant fault (in which no input test pattern is possible or required) or a non-redundant fault for which an input test pattern is determined. In the multiple-fault approach, an equivalent locked logic circuit 220 is generated based on the logic circuit 218 for all of the remaining faults, and a Boolean satisfiability (SAT) attack is performed to determine one or more input test patterns for those remaining faults. The computing device 102 uses those input test patterns and a simulation of the logic circuit 218 to identify redundant faults (e.g., those undetected faults that were represented in the locked logic circuit 220 but not covered by the input test patterns). The input test patterns determined by the multiple-fault approach may be reduced in size and/or otherwise optimized compared to the input test patterns determined by the single-fault approach. One potential embodiment of a method for a multiple-fault approach is described further below in connection with FIG. 7.

After determining input test patterns in block 314 and/or block 316 as described above, the computing device 102 may test the device under test 106 with those input test patterns. The computing device 102 may, for example, provide the input test patterns to the test device 104 or other IC tester, which may test the device under test 106. The test device 104 may sequentially provide each of the input test patterns X to a device under test 106 and receive outputs Y in response to those inputs X. The test device 104, the computing device 102, and/or another device may compare those outputs Y to a predetermined set of expected outputs for the device under test 106. Any difference between the measured outputs Y and the expected outputs indicates a fault in the device under test 106. As described above, the input test patterns provided by the computing device 102 have 100% coverage for non-redundant stuck-at faults that may occur in the device under test 106. After testing the device under test 106, the method 300 is completed. Testing with the input test patterns may proceed for multiple instances of the device under test 106. The method 300 may be executed again, for example to analyze a different device under test 106.

Referring now to FIG. 4, in use, the computing device 102 may execute a method 400 for a single-fault approach for determining test patterns and identifying redundant faults. The method 400 may be executed, for example, in connection with block 314 of FIG. 3, described above. It should be appreciated that, in some embodiments, the operations of the method 400 may be performed by one or more components of the environment 200 of the computing device 102 as shown in FIG. 2. The method 400 begins with block 402, in which the computing device 102 inserts a key gate in the logic circuit 218 at the location of a stuck-at fault to generate a locked logic circuit 220 with a one-bit key k. The particular key gate inserted depends on whether the stuck-at fault is a stuck-at-0 (sa0) fault or a stuck-at-1 (sa1) fault. In some embodiments, in block 404 the computing device 102 may insert one or more buffers into the logic circuit 218 for a logical fanout segment. For example, the computing device 102 may insert a buffer to isolate a stuck-at fault from other segments in a fanout at the same node. In some embodiments, in block 406 the computing device 102 may insert an AND key gate for a stuck-at-0 fault. The inserted AND gate receives as inputs the original signal of the stuck-at-0 fault and the 1-bit key k. The output of the inserted AND gate is connected the same way as the original signal of the stuck-at-0 fault. In some embodiments, in block 408 the computing device 102 may insert an OR key gate for a stuck-at-1 fault. The inserted OR gate receives as inputs the original signal of the stuck-at-1 fault and the 1-bit key k. The output of the inserted OR gate is connected the same way as the original signal of the stuck-at-1 fault.

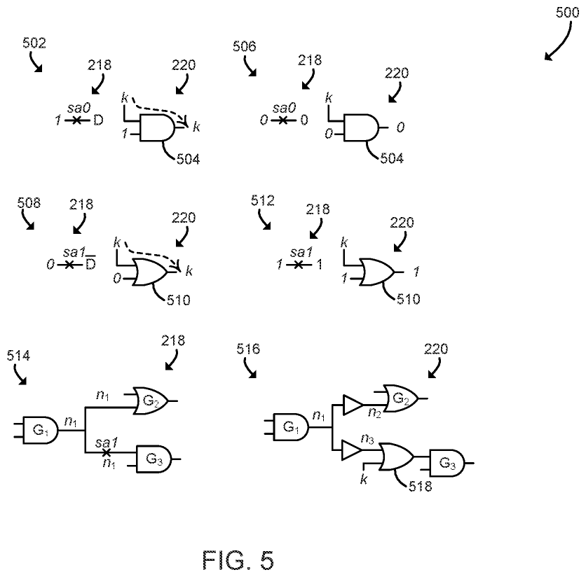

Referring now to FIG. 5, diagram 500 illustrates various key gates that may be inserted as described above in connection with block 402. Sub-diagram 502 illustrates a stuck-at-0 fault sa0 in the logic circuit 218 that is replaced with an AND gate 504 in the locked logic circuit 220. As shown in the sub-diagram 502, when the input to sa0 is logic 1, then the value of the key k is propagated to the output of the gate 504. Sub-diagram 506 illustrates the same stuck-at-0 fault sa1 with input logic set to logic 0. As shown, when the input to sa0 is logic 0, then the output of the gate 504 is always 0, regardless of the value of k. Accordingly, as described further below, logic 1 is a distinguishing input value for sa0, because with the input set to 1, the output is different for different values of the key k. Accordingly, the locked circuit 220 of sub-diagram 502 may be used to model the stuck-at-0 fault sa0 when input is set to 1, because when k is set to 0, then output of the gate is 0 rather than the expected 1.

Sub-diagram 508 illustrates a stuck-at-1 fault sa1 in the logic circuit 218 that is replaced with an OR gate 510 in the locked logic circuit 220. As shown in the sub-diagram 508, when the input to sa1 is logic 0, then the value of the key k is propagated to the output of the gate 510. Sub-diagram 512 illustrates the same stuck-at-1 fault sa1 with input logic set to logic 1. As shown, when the input to sa1 is logic 1, then the output of the gate 510 is always 1, regardless of the value of k. Accordingly, as described further below, logic 0 is a distinguishing input value for sa1, because with the input set to 0, the output is different for different values of the key k. Accordingly, the locked circuit 220 of sub-diagram 508 may be used to model the stuck-at-1 fault sa1 when input is set to 0, because when k is set to 1, then output of the gate is 1 rather than the expected 0.

Sub-diagram 514 illustrates a logic circuit 218 with a stuck-at-1 fault sa1 positioned between gates G₁ and G₃. As shown, the gate G₁ has a multiple fanout segments to both gates G₂ and G₃. Accordingly, the output from the gate G₁ and the inputs to gates G₂ and G₃ are all included in the same node n₁. Sub-diagram 516 illustrates a locked logic circuit 220 that is equivalent to the circuit 218 of sub-diagram 514. As shown, two buffers have been inserted into the fanout segments of gate G₁. These buffers separate node mi from new nodes n₂ and n₃. An OR gate 518 has been inserted in node n₃ to model the stuck-at-1 fault sa1 at the input of the gate G₃. Similar to sub-diagram 508 described above, when node n₃ is at logic 0, then the value of the key k is propagated to the output of the gate 518. Accordingly, an input pattern that results in a value of logic 0 at the node n₃ may be a discriminating input pattern for the stuck-at-1 fault shown in sub-diagrams 514, 516.

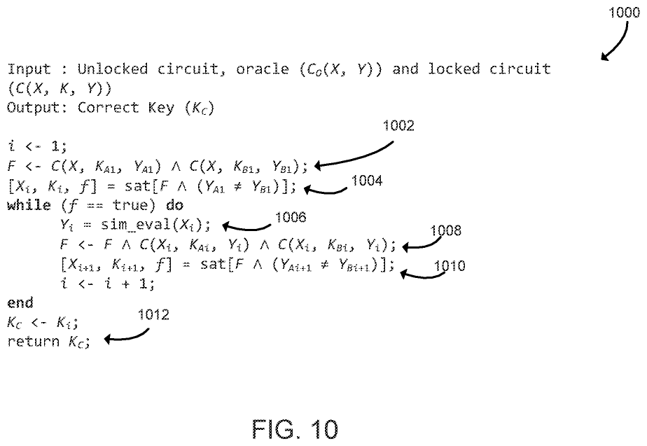

Referring back to FIG. 4, after inserting the key gate into the logic circuit 218 to generate a locked logic 220, in block 410 the computing device 102 performs an initial iteration of a Boolean satisfiability (SAT) attack with a 1-bit key on the locked logic circuit 220 using the original logic circuit 218 as an oracle. As part of the SAT-attack, the computing device 102 constructs a miter circuit in which the locked circuit 220 is replicated twice (e.g., two copies of the locked circuit 220). Each copy of the locked circuit 220 receives the same input X (which may be a vector of logic values), but different keys k. Because the locked circuit 220 includes a single-bit key k, one copy of the locked circuit 220 receives k=0 and the other copy of the locked circuit 220 receives k=1. The output bits from the copies of the locked circuit 220 are XORed and then ORed together, so that a logic one at the final output of the miter circuit indicates a mismatch between the output of the locked circuits 220. In the initial iteration of the SAT-attack, the computing device 102 determines whether an input pattern X exists that will result in the output of the miter circuit equaling logic 1. If so, the miter circuit is satisfiable, and if not, the miter circuit is not satisfiable. If the miter circuit is satsifiable, then the input pattern X assigned by the SAT solver is a distinguishing pattern, which means that given this input pattern, the output of the locked circuit 220 changes depending on the value of k. Accordingly, this input pattern may be used to detect the stuck-at fault corresponding to the key k. One potential embodiment of an algorithm for the SAT-attack is described further below in connection with FIG. 10.

In block 412, the computing device 102 determines whether the locked circuit 220 is satisfiable or not. For example, the computing device 102 may determine whether the SAT-solver found an input test pattern that satisfied the miter circuit as described above. If not, the method 400 branches to block 414, in which the computing device 102 identifies the current stuck-at fault as a redundant faults. Redundant faults do not affect the output of the logic circuit 218. Accordingly, no distinguishing input pattern exists for redundant faults, and no test coverage is needed. After identifying the fault as a redundant fault, the method 400 branches ahead to block 422, in which the computing device 102 determines whether additional stuck-at faults remain for analysis. If so, the method 400 loops back to block 402 to analyze the next remaining stuck-at fault. If no faults remain, the method 400 is completed.

Referring back to block 412, if the computing device 102 determines that the locked circuit 220 is satisfiable, the method 400 advances to block 416, in which the computing device 102 receives a distinguishing input pattern (DIP) and a key k from the SAT-attack solver. As described above, the SAT-attack solver constructs a miter circuit and determines whether an input pattern exists for which different results are produced for different key values. This input pattern is a DIP. As further described above, the key k is a 1-bit key having a value of 0 or 1. The computing device 102 may determine the correct value of the key k by comparing output from the locked logic circuit 220 given the DIP X and each k=0 or 1 with output from the original logic circuit 218 given the DIP X. Output values for the correct key k will match between the original logic circuit 218 and the locked logic circuit 220.

In block 418, the computing device 102 verifies that the returned key value k matches an expected key value k_{ref} for the stuck-at-fault being analyzed. As described above, for stuck-at-0 faults, expected key value k_{ref} is 1, and for stuck-at-1 faults, the expected key value k_{ref} is 0. If the key k does not match the expected key value k_{ref}, then an error has likely occurred, and the computing device 102 may signal an exception or otherwise indicate the error.

In block 420, the computing device 102 saves the DIP as an input test pattern for the current stuck-at fault. The method 400 advances to block 422, in which the computing device 102 determines whether additional stuck-at faults remain for analysis. If so, the method 400 loops back to block 402 to analyze the next remaining stuck-at fault. If no faults remain, the method 400 is completed.

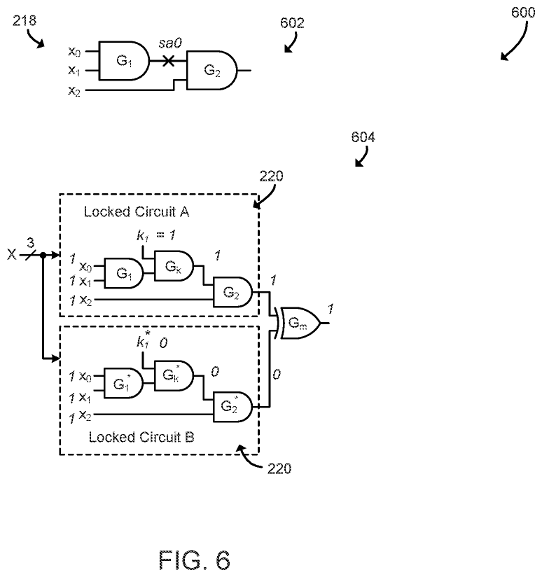

Referring now to FIG. 6, diagram 600 illustrates one potential embodiment miter circuit that may be constructed and analyzed by the SAT-attack solver as described above in connection with the method 400 of FIG. 4. Sub-diagram 602 illustrates a logic circuit 218 that may be analyzed. As shown, the logic circuit 218 includes a single stuck-at-0 fault sa0 on the signal between gates G₁ and G₂. Sub-diagram 604 illustrates a miter circuit that may be constructed by the SAT-attack solver. As shown, the miter circuit includes two copies of the locked logic circuit 220 that corresponds to the logic circuit 218 of sub-diagram 602. Each of the locked logic circuits 220 receive the same input X, which is a vector of three values x₀, x₁, and x₂. Locked Circuit A receives key k₁=1, and Locked Circuit B receives key k₂=0. Output from both locked logic circuits 220 is provided to miter XOR gate Gₘ. Accordingly, output from the gate Gₘ is 1 when output from each of the locked logic circuits 220 differ. To solve the Boolean satisfiability problem, the computing device 102 identifies an input X such that output from the gate Gₘ is one. The computing device 102 may initially assume the output of Locked Circuit A is logic 1. Based on that assumption, all literals in the miter can be iteratively implied without raising a conflict or backtracking, resulting in DIP X={1, 1, 1} as shown. Note that if the computing device initially assumes the output of Locked Circuit A is logic 0, then a conflict arises at the output of the key gate Gr, which may be resolved locally (e.g., with conflict-driven clause learning (CDCL)) without having to trace back the entire miter circuit. Accordingly, the computing device 102 may identify the DIP more efficiently and with less backtracking than previous techniques.

Referring now to FIG. 7, in use, the computing device 102 may execute a method 700 for a multiple-fault approach for determining test patterns and identifying redundant faults. The method 700 may be executed, for example, in connection with block 316 of FIG. 3, described above. It should be appreciated that, in some embodiments, the operations of the method 700 may be performed by one or more components of the environment 200 of the computing device 102 as shown in FIG. 2. The method 700 begins with block 702, in which the computing device 102 inserts a key gate in the logic circuit 218 at the location of each stuck-at fault from a collection of n faults to generate a locked logic circuit 220 with an n-bit key Kₙ. The particular key gate inserted for each fault depends on whether the stuck-at fault is a stuck-at-0 (sa0) fault or a stuck-at-1 (sa1) fault. In some embodiments, in block 704 the computing device 102 may insert one or more buffers into the logic circuit 218 for a logical fanout segment. For example, the computing device 102 may insert a buffer to isolate a stuck-at fault from other segments in a fanout at the same node. In some embodiments, in block 706 the computing device 102 may insert an AND key gate for a stuck-at-0 fault. The inserted AND gate receives as inputs the original signal of the stuck-at-0 fault and one of the bits of the key K. The output of the inserted AND gate is connected the same way as the original signal of the stuck-at-0 fault. In some embodiments, in block 408 the computing device 102 may insert an OR key gate for a stuck-at-1 fault. The inserted OR gate receives as inputs the original signal of the stuck-at-1 fault and one of the bits of the key K. The output of the inserted OR gate is connected the same way as the original signal of the stuck-at-1 fault.

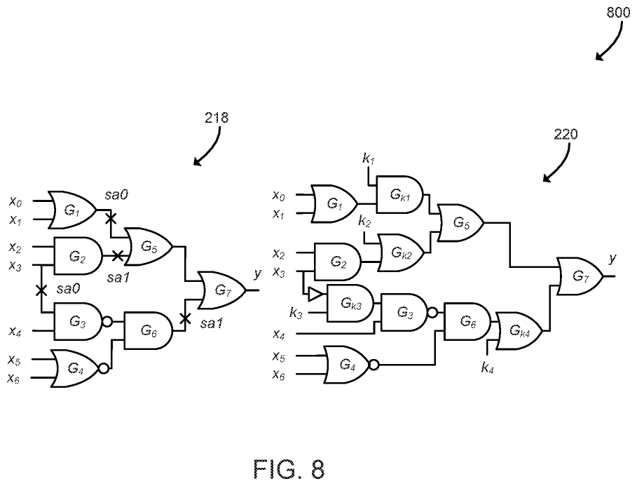

Referring now to FIG. 8, diagram 800 illustrates an example logic circuit 218 and a corresponding locked logic circuit 220 that may be generated by the computing device 102. As shown, the logic circuit 218 includes four stuck-at faults (two sa0 and two sa1). The locked logic circuit 220 includes four corresponding key gates Gₖ₁ through Gₖ₄, which are connected to corresponding key bits k₁ through k₄. Accordingly, the illustrative locked logic circuit 220 has a four-bit key K={k₁, k₂, k₃, k₄}. Note that a buffer has been inserted to separate the key gate Gₖ₁ at the input of gate G₃ from the input of gate G₂.

Referring again to FIG. 7, in block 710 the computing device 102 performs all iterations of the SAT-attack with the n-bit key on the locked logic circuit 220 using the original logic circuit 218 as an oracle. As described above, in each iteration of the SAT-attack, the solver constructs a miter circuit using two potential key values and determines whether a distinguishing input pattern (DIP) X exists that produces different output for different key values. If so, this DIP is recorded, and the logic circuit 218 oracle is used to determine the correct output Y. The equivalence class of all keys K that produce incorrect output are stored in solver assumptions and thus removed from the search space. The SAT-attack continues additional iterations until all DIPs are found. In the last iteration, when the miter is not satisfiable and no DIP can be found, the remaining key in the keyspace is the key K for the locked logic circuit 220.

In block 712, the computing device 102 receives zero or more DIPs and the n-bit key Kₙ from the SAT-attack solver. Each of the returned DIPs is an input test pattern for one or more of the n stuck-at faults. If zero DIPs are returned, then all of the n faults are redundant.

In block 714, the computing device 102 validates the key Kₙ by checking its individual bits with an expected key value for the corresponding stuck-at fault. As described above, for stuck-at-0 faults, expected key value k_{ref} is 1, and for stuck-at-1 faults, the expected key value k_{ref} is 0. If any bit of the key Kₙ does not match the corresponding expected key value k_{ref}, then an error has likely occurred, and the computing device 102 may signal an exception or otherwise indicate the error.

In block 716, the computing device 102 saves the returned DIPs as test patterns for the n faults. As described above, each of the DIPs is an input test pattern for one or more of the faults. In block 718, the computing device 102 identifies detected and redundant faults using fault simulation with the logic circuit 218. As described above, redundant faults have no effect on outputs of the logic circuit 218. Accordingly, the computing device 102 may determine simulate each fault in the logic circuit 218 for each of the identified DIPs. For any fault that does not generate differential output for any of the DIPs, that fault is a redundant fault. After identifying detected and redundant faults, the method 700 is completed.

Referring again to FIG. 8, in an illustrative example, the computing device 102 may perform the SAT-attack on the locked logic circuit 220 shown in the diagram 800. As described above, the illustrative locked logic circuit 220 has a four-bit key vector {k₀,k₁,k₂,k₃}, and thus has an initial key space with 16 potential values for the key vector. In an initial iteration, the SAT-solver may identify a DIP {x₀,x₁, . . . , x₆}={1001 100}. Based on this pattern, the computing device 102 removes the key vector {k₀,k₁,k₂,k₃}={0010} because this key with the DIP {1001100} produces the incorrect result y as compared to the original logic circuit 218. In the next iteration, the SAT-solver may identify a DIP {x₀, x₁, . . . , x₆}= {0001100}. This computing device 102 may remove 14 additional keys from the key space that all produce incorrect results for this DIP, leaving key vector {k₀,k₁,k₂,k₃}={1010} as the last remaining key in the key space. In the next iteration, no further DIP is found with only {k₀,k₁,k₂,k₃}={1010} in the key space. Accordingly, based on the results from the SAT-attack solver, the computing device 102 determines that the locked logic circuit 220 has two DIPs P₁, P₂={1001100}, {0001100}, and that the key vector {k₀,k₁,k₂,k₃}={1010}. The computing device 102 may verify that this key vector is correct based on the stuck-at faults being analyzed, and may identify P₁, P₂= {1001100}, {0001100} as input test patterns for the logic circuit 218. Note that the multi-fault approach in this example returns two input test patterns, which is less than the four input test patterns that would be determined if each of the four stuck-at faults were analyzed with the single-fault approach described above in connection with FIG. 4.

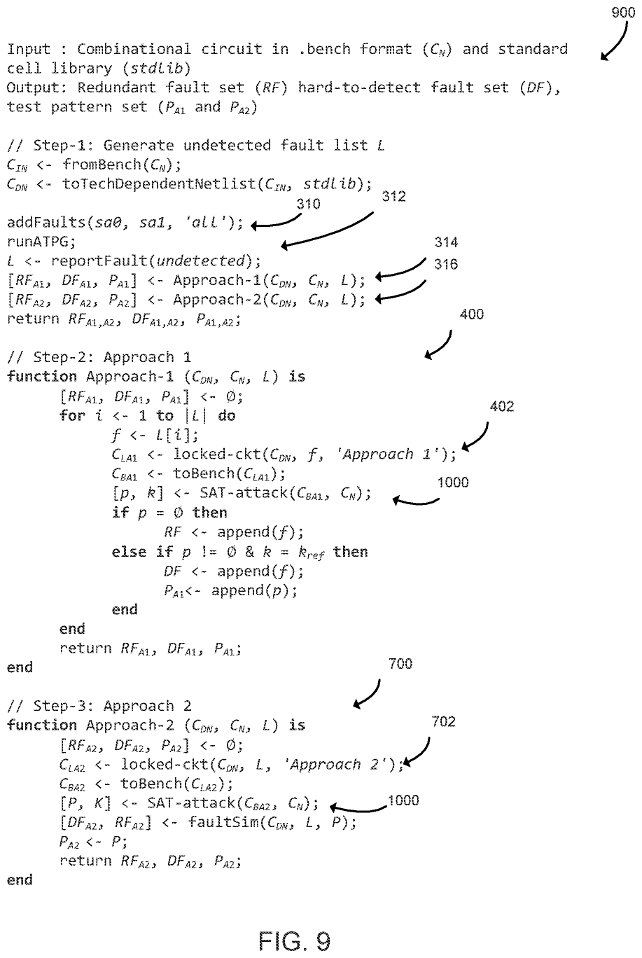

Referring now to FIG. 9, pseudocode 900 illustrates one potential embodiment of a method for automatically test pattern generation that may be executed by the computing device 102. The method shown in pseudocode 900 accepts as input a combinational circuit in the .bench file format (C_{N}) and a standard cell library (stdlib) that corresponds to a particular logic technology. The combinational circuit C_{N} corresponds to the logic circuit 218. The pseudocode 900 outputs a redundant fault set RF, a hard-to-detect fault set DF, and test pattern sets P_{A1} and P_{A2}. The redundant faults RF include those faults that do not affect the output of the combinational circuit C_{N} and thus are not included in test pattern coverage. The hard-to-detect fault set DF includes all stuck-at faults in the combinational circuit C_{N} that were not detected by a conventional automatic test pattern generation (ATPG) tool. Similarly, the test pattern sets P_{A1} and P_{A2} cover all of the hard-to-detect faults in the set DF. Thus, complete test pattern coverage may be achieved by combining the test pattern sets P_{A1} and P_{A2} with test patterns produced by the conventional ATPG tool. In some embodiments, the pseudocode 900 may convert or otherwise process sequential logic (not shown) to generate the combinational circuit C_{N}.

In a code segment labeled Step-1, the pseudocode 900 generates an undetected fault list L from the circuit C_{N}. The pseudocode loads the circuit C_{N} from the .bench format into a technology-independent netlist C_{IN} and then maps the circuit to a technology dependent netlist C_{DN} using the standard cell stdlib. The pseudocode 900 then adds stuck-at-0 faults and stuck-at-1 faults to all signals, lines, wires, or other appropriate locations in the netlist C_{DN}, as described above in connection with block 310 of FIG. 3.

After assigning the sa0 and sa1 faults, the pseudocode 900 calls the conventional ATPG tool and collects any faults that were not detected by the conventional ATPG tool into the undetected faults L, as described above in connection with block 312 of FIG. 3. The pseudocode 900 may perform any other configuration or setup tasks that are appropriate in connection with the ATPG tool. For example, in some embodiments, the pseudocode 900 may generate a test protocol tp in SPF format (not shown), for example from netlist synthesis or directly by the ATPG tool. As another example, the pseudocode 900 may configure the ATPG tool to increase fault coverage, for example, by increasing the allotted number of backtracks, setting the abort limit to maximum, or otherwise configuring the ATPG tool.

After determining the undetected faults L, the pseudocode 900 calls the function Approach-1 to determine redundant faults RF, hard-to-detect faults DF, and test patterns P_{A1} using the single-fault approach as described above in connection with block 314 of FIG. 3. The pseudocode 900 next calls the function Approach-2 to determine redundant faults RF, hard-to-detect faults DF, and test patterns P_{A1} using the multiple-fault approach as described above in connection with block 316 of FIG. 3. The pseudocode 900 returns the redundant faults RF, the hard-to-detect faults DF, and the test patterns P_{A1}, P_{A2} determined using both the single-fault approach and the multiple-fault approach.

The pseudocode 900 further includes a function Approach-1 which corresponds to the method 400 described above in connection with FIG. 4. As shown, as part of the function, for each fault f in the list of undetected faults L, the pseudocode 900 converts the netlist CON to the locked circuit C_{LA1}, which corresponds to the locked circuit 220, as described above in connection with block 402 of FIG. 4. The pseudocode 900 calls a SAT-attack function on the locked circuit C_{BA1} (in .bench format) with the original circuit C_{N} as an oracle. One potential embodiment of an SAT-attack function 1000 is described below in connection with FIG. 10. As shown, the SAT-attack function returns a distinguishing input pattern (DIP) p and a key k. If the DIP p is empty (i.e., not found), then the current fault f is appended to the redundant faults RF. If the DIP p is not empty, and the key k matches the expected k_{ref} for the current fault f, then the current fault f is appended to the hard-to-detect faults DF and the DIP p is appended to the test input patterns P_{A1}. Note that every fault f should belong to either RF or DF, and thus the key k returned by the SAT-attack should always match the expected k_{ref}. Iterations of this procedure continue until all faults fin the undetected faults L have been processed.

The pseudocode 900 further includes a functional Approach-2 which corresponds to the method 700 described above in connection with FIG. 7. As shown, as part of the function, the pseudocode 900 converts the netlist CON to the locked circuit C_{LA2}, which corresponds to the locked circuit 220, as described above in connection with block 702 of FIG. 7. As a key gate is inserted for every undetected fault in L, the locked circuit 220 should include |Z| key gates. The pseudocode 900 calls the SAT-attack function on the locked circuit C_{BA2} (in .bench format) with the original circuit C_{N} as an oracle. One potential embodiment of the SAT-attack function 1000 is described below in connection with FIG. 10. As shown, the SAT-attack function returns a set of distinguishing input patterns (DIPs) P and an |Z|-bit key vector K. Redundant faults RF and hard-to-detect faults DF are determined using fault simulation as a function of the netlist of the original circuit C_{N}, the list of undetected faults L, and the set of DIPs P. As the key K is correctly determined, the test patterns P must detect all faults except redundant faults that do not impact functionality of the logic circuit. Thus, undetected faults from this fault simulation must be redundant. The test input patterns P_{A2} is set to the set of DIPs P returned by the SAT-attack function. Note that because the locked circuit C_{LA2} models all of the undetected faults L, only one iteration of this process is performed.

Referring now to FIG. 10, pseudocode 1000 illustrates one potential embodiment of a method for a Boolean satisfiability attack. This method 1000 may correspond to the function SAT-attack called in the pseudocode 900 of FIG. 9. As shown, the method 1000 receives as input an oracle C_{O}(X, Y) corresponding to the logic circuit 218 and a locked circuit C(X, K, Y) corresponding to the locked logic circuit 220. The method 1000 outputs the correct key K_{C}. As described above, when K=K_{C}, output of the locked circuit C(X, K_{C}, Y) matches output of the oracle C_{O}(X, Y).

In an initialization step at line 1002, the pseudocode 1000 constructs the miter circuit in which the locked circuit is replicated twice, C (X, K_{A1}, Y_{A1}), C (X, K_{B1}, Y_{B1}). The SAT-attack algorithm iteratively removes equivalence classes of incorrect keys. In each ith iteration of the SAT-attack, the pseudocode queries the Boolean satisfiability (SAT) solver, abstracted as the function “sat” at lines 1004, 1010, with the miter circuit and the constraint that the corresponding output of the two copies of the locked circuit are different (Y_{A1}≠Y_{B1}). The SAT solver may be embodied as any appropriate Boolean satisfiability algorithm, such as a conflict-driven clause learning (CDCL) algorithm. At each ith round of the SAT-attack, the SAT solver find a distinguishing input pattern Xᵢ along with assigning f==true. When a distinguishing input pattern Xᵢ is found, the actual output Yᵢ for this input Xᵢ is obtained from oracle simulation using the function sim_eval at line 1006. Both the distinguishing input X; and the actual output Y; are stored in the solver assumptions at line 1008 and carried to subsequent iterations. By appending this input-output pair {Xᵢ, Yᵢ} to the conjunctive normal form (CNF) in F, any incorrect key combinations that produces output other than Yᵢ for Xᵢ is removed from the key space in subsequent iterations. The input-output pairs are accumulated so that, at the subsequent iteration, the distinguishing input pattern that the SAT solver finds not only creates differential output for the miter circuit but also satisfies all of the input-output constraint pairs of the previous findings. The SAT-attack continues to eliminate incorrect key classes and shrinks key space until no more distinguishing input patterns can be found, and then assigns f==false, which implies no more incorrect keys remain. The pseudocode 1000 returns the key assignment of the last iteration as the correct key K_{C}. Note that if multiple keys remain in the keyspace with no more distinguishing input patterns, then all of those keys are in the same equivalence class.

1. A computing device for logic circuit test pattern generation, the computing device comprising:
a logic preprocessor to identify a first stuck-at fault for testing with a logic circuit, wherein the first stuck-at fault is associated with a first signal of the logic circuit and a digital logic stuck-at value;
a lock circuit generator to insert a key gate in the logic circuit at the first stuck-at fault for testing to generate a locked logic circuit, wherein the key gate receives a key value and a value of the first signal associated with the first stuck-at fault, and wherein when the key value is a first key value the key gate generates the digital logic stuck-at value, and wherein when the key value is a second key value the key gate propagates the value of the first signal; and
a fault analyzer to (i) determine whether an input test pattern associated with the first stuck-at fault exists by performance of a Boolean satisfiability attack on the locked logic circuit, and (ii) identify the first stuck-at fault as a redundant fault in response to a determination that an input test pattern associated with the first stuck-at fault does not exist.

2. The computing device of claim 1, further comprising a test manager to (i) input the input test pattern associated with the first stuck-at fault to a device under test that comprises the logic circuit and (ii) compare an output pattern received from the logic circuit of the device under test in response to inputting of the input test pattern to an expected output.

3. The computing device of claim 1, wherein the first stuck-at fault comprises a stuck-at-1 fault or a stuck-at-0 fault.

4. The computing device of claim 1, wherein to insert the key gate in the logic circuit at the first stuck-at fault comprises to insert an AND gate for a stuck-at-1 fault and to insert an OR gate for a stuck-at-0 fault.

5. The computing device of claim 1, wherein to insert the key gate in the logic circuit further comprises to insert a buffer at a logic fanout segment in the logic circuit.

6. The computing device of claim 1, further comprising an automatic test pattern generation tool to:
perform an automatic test pattern generation process with the logic circuit; and
identify a plurality of undetected stuck-at faults in the logic circuit in response to performance of the automatic test pattern generation process;
wherein the plurality of undetected stuck-at faults comprises the first stuck-at fault.

7. The computing device of claim 1, wherein:
the logic preprocessor is to identify a plurality of stuck-at faults, the plurality of stuck-at faults comprising the first stuck-at fault;
the lock circuit generator is to, for each stuck-at fault of the plurality of stuck-at faults, insert a key gate in the logic circuit at the corresponding stuck-at fault to generate a plurality of locked logic circuits; and
the fault analyzer is to, for each stuck-at fault of the plurality of stuck-at faults, (i) determine whether an input test pattern associated with the corresponding stuck-at fault exists by performance of the Boolean satisfiability attack on each locked logic circuit of the plurality of locked logic circuits and (ii) identify the corresponding stuck-at fault as a redundant fault in response to a determination that an input test pattern associated with the corresponding stuck-at fault does not exist.

8. The computing device of claim 7, wherein to determine whether an input test pattern associated with the corresponding stuck-at fault exists comprises to:
perform an iteration of the Boolean satisfiability attack on the corresponding locked logic circuit;
determine whether the corresponding locked logic circuit is satisfiable in response to performance of the iteration of the Boolean satisfiability attack; and
determine that the corresponding stuck-at fault is a redundant fault in response to a determination that the corresponding locked logic circuit is not satisfiable.

9. The computing device of claim 8, wherein to determine the input test pattern associated with the corresponding stuck-at fault comprises to:
determine a distinguishing input pattern for the corresponding locked logic circuit in response to a determination that the corresponding locked logic circuit is satisfiable, wherein the input test pattern comprises the distinguishing input pattern.

10. The computing device of claim 1, wherein:
the logic preprocessor is to identify a plurality of stuck-at faults, the plurality of stuck-at faults comprising the first stuck-at fault;
the lock circuit generator is to insert a plurality of key gates in the logic circuit to generate the locked logic circuit, wherein each key gate corresponds to a stuck-at fault of the plurality of stuck-at faults; and
the fault analyzer is to determine an input test pattern associated with each stuck-at fault of the plurality of stuck-at faults that is not a redundant fault by the performance of the Boolean satisfiability attack on the locked logic circuit.

11. The computing device of claim 10, wherein to perform the Boolean satisfiability attack comprises to determine a plurality of distinguishing input patterns for the locked logic circuit, wherein the plurality of distinguishing input patterns comprises the input test pattern associated with each stuck-at fault that is not a redundant fault.

12. A method for logic circuit test pattern generation, the method comprising:
identifying, by a computing device, a first stuck-at fault for testing with a logic circuit, wherein the first stuck-at fault is associated with a first signal of the logic circuit and a digital logic stuck-at value;
inserting, by the computing device, a key gate in the logic circuit at the first stuck-at fault for testing to generate a locked logic circuit, wherein the key gate receives a key value and a value of the first signal associated with the first stuck-at fault, and wherein when the key value is a first key value the key gate generates the digital logic stuck-at value, and wherein when the key value is a second key value the key gate propagates the value of the first signal;
determining, by the computing device, whether an input test pattern associated with the first stuck-at fault exists by performing a Boolean satisfiability attack on the locked logic circuit; and
identifying, by the computing device, the first stuck-at fault as a redundant fault in response to determining that an input test pattern associated with the first stuck-at fault does not exist.

13. The method of claim 12, further comprising:
inputting, by the computing device, the input test pattern associated with the first stuck-at fault to a device under test that comprises the logic circuit; and
comparing, by the computing device, an output pattern received from the logic circuit of the device under test in response to inputting the input test pattern to an expected output.

14. The method of claim 12, further comprising:
performing, by the computing device, an automatic test pattern generation process with the logic circuit; and
identifying, by the computing device, a plurality of undetected stuck-at faults in the logic circuit in response to performing the automatic test pattern generation process;
wherein the plurality of undetected stuck-at faults comprises the first stuck-at fault.

15. The method of claim 12, further comprising:
identifying, by the computing device, a plurality of stuck-at faults, the plurality of stuck-at faults comprising the first stuck-at fault;
inserting, by the computing device, for each stuck-at fault of the plurality of stuck-at faults, a key gate in the logic circuit at the corresponding stuck-at fault to generate a plurality of locked logic circuits;
determining, by the computing device, for each stuck-at fault of the plurality of stuck-at faults, whether an input test pattern associated with the corresponding stuck-at fault exists by performing the Boolean satisfiability attack on each locked logic circuit of the plurality of locked logic circuits; and
identifying, by the computing device, for each stuck-at fault of the plurality of stuck-at faults, the corresponding stuck-at fault as a redundant fault in response to determining that an input test pattern associated with the corresponding stuck-at fault does not exist.

16. The method of claim 12, further comprising:
identifying, by the computing device, a plurality of stuck-at faults, the plurality of stuck-at faults comprising the first stuck-at fault;
inserting, by the computing device, a plurality of key gates in the logic circuit to generate the locked logic circuit, wherein each key gate corresponds to a stuck-at fault of the plurality of stuck-at faults; and
determining, by the computing device, an input test pattern associated with each stuck-at fault of the plurality of stuck-at faults that is not a redundant fault by performing the Boolean satisfiability attack on the locked logic circuit.

17. One or more non-transitory, computer-readable media comprising a plurality of instructions that, when executed, cause a computing device to:
identify a first stuck-at fault for testing with a logic circuit, wherein the first stuck-at fault is associated with a first signal of the logic circuit and a digital logic stuck-at value;
insert a key gate in the logic circuit at the first stuck-at fault for testing to generate a locked logic circuit, wherein the key gate receives a key value and a value of the first signal associated with the first stuck-at fault, and wherein when the key value is a first key value the key gate generates the digital logic stuck-at value, and wherein when the key value is a second key value the key gate propagates the value of the first signal;
determine an input test pattern associated with the first stuck-at fault exists by performing a Boolean satisfiability attack on the locked logic circuit; and
identify the first stuck-at fault as a redundant fault in response to determining that an input test pattern associated with the first stuck-at fault does not exist.

18. The one or more non-transitory, computer-readable media of claim 17, further comprising a plurality of instructions that, when executed, cause the computing device to:
perform an automatic test pattern generation process with the logic circuit; and
identify a plurality of undetected stuck-at faults in the logic circuit in response to performing the automatic test pattern generation process;
wherein the plurality of undetected stuck-at faults comprises the first stuck-at fault.

19. The one or more non-transitory, computer-readable media of claim 17, further comprising a plurality of instructions that, when executed, cause the computing device to:
identify a plurality of stuck-at faults, the plurality of stuck-at faults comprising the first stuck-at fault;
for each stuck-at fault of the plurality of stuck-at faults, insert a key gate in the logic circuit at the corresponding stuck-at fault to generate a plurality of locked logic circuits; and
determine, for each stuck-at fault of the plurality of stuck-at faults, whether an input test pattern associated with the corresponding stuck-at fault exists by performing the Boolean satisfiability attack on each locked logic circuit of the plurality of locked logic circuits; and
identify, for each stuck-at fault of the plurality of stuck-at faults, the corresponding stuck-at fault as a redundant fault in response to determining that an input test pattern associated with the corresponding stuck-at fault does not exist.

20. The one or more non-transitory, computer-readable media of claim 17, further comprising a plurality of instructions that, when executed, cause the computing device to:
identify a plurality of stuck-at faults, the plurality of stuck-at faults comprising the first stuck-at fault;
insert a plurality of key gates in the logic circuit to generate the locked logic circuit, wherein each key gate corresponds to a stuck-at fault of the plurality of stuck-at faults; and
determine an input test pattern associated with each stuck-at fault of the plurality of stuck-at faults that is not a redundant fault by performing the Boolean satisfiability attack on the locked logic circuit.
